(19) United States
(12) Patent Application Publication
(10) Pub. No.: US 2002/0090813 A1
(43) Pub. Date: Jul. 11, 2002

(54) Method for forming a dual damascene opening by liquid phase deposition

(75) Inventor: Sun-Chieh Chien, Hsin-Chu City (TW)

Correspondence Address: LOWE HAUPTMAN GILMAN & BERNER, LLP, Suite 310, 1700 Diagonal Raod, Alexandria, VA, 22314, US

(73) Assignee: UNITED MICROELECTRONICS CORP.

(21) Appl. No.: 09/755,104

(22) Filed: Jan. 8, 2001

(51) Int. Cl. H01L 21/4763; H01L 21/31; H01L 21/469

(52) U.S. Cl. 438/638; 438/787

(57) ABSTRACT

The present invention provides a method to form a dual damascene opening by a liquid phase deposition method. The method can avoid the photoresist left in the via hole and the etching profile of the trench distorted, such will affect the formation of dual damascene opening. The liquid phase deposition is a selectively depositing method, so silicon dioxide will be deposited on the dielectric layer but not on the photoresist. The liquid phase deposition is performed at a temperature range from about 25° C. to about 40° C., which is different from those prior deposition methods which are carried out at a temperature about several hundred degrees centigrade. The liquid used in the liquid phase deposition method was prepared by dissolving highly purified silica particles in hydrofluosilicic acid at 35° C.

### BACKGROUND

1. Field of the Invention

The present invention generally relates to a method for forming a dual damascene opening, and in particular to a method for forming a dual damascene opening by liquid phase deposition.

2. Description of the Prior Art

The dual damascene process is an important method to manufacture multi-level interconnects. A dual damascene opening is shown in FIG. 1. A conductor 101, such as an interconnect or an MOS, is provided, and an inter-metal dielectric layer 102 is formed to cover the conductor 101. A dual damascene opening 103 is formed in the inter-metal dielectric layer 102, and the opening consists of a trench 103A used for interconnect and a via hole 103B.

There are two conventional methods for forming a dual damascene opening: one is the trench-first method in which a trench is firstly formed and a via hole is then formed; the other is via-first method in which a via hole is firstly formed and a trench is then formed.

The manufacturing process of the via-first method is shown form FIG. 2A to FIG. 2E. Firstly, a conductor 201 is provided. Then a inter-metal dielectric (IMD) layer 202 is formed on the surface of the conductor 201, as shown in FIG. 2A. Secondly, a photoresist 203 is formed on the inter-metal dielectric layer 202 and is patterned to define a via hole. The inter-metal dielectric layer 202 is then etched to form a via hole 204. As shown in FIG. 2B, the photoresist 203 is then removed. Then, another photoresist 205 is deposited on the surface of the inter-metal dielectric layer 202 and the via hole 204 is filled up, as shown in FIG. 2C. Then, the photoresist 205 is patterned to define a trench, and the unnecessary part of photoresist on the inter-metal dielectric layer and in the via hole is removed to form a photoresist mask 206 and via hole 207, as shown in FIG. 2D. Finally, the inter-metal dielectric layer 202 is etched to form a dual damascene opening 208, as shown in FIG. 2E, which consisted of a trench 208A and a via hole 208B.

However, there is a problem existed in the via-first method. In the step of removing the unnecessary photoresist in the via hole, the exposure of the photoresist near the bottom of the via hole is insufficient, since a depth of the via hole exists and will become deeper after the photoresist is deposited on the inter-metal dielectric layer. Thus, the photoresist in the via hole cannot be removed completely, and residue of photoresist appears. If we increase the extent of exposure to completely remove the photoresist in the via hole, the boundary of trench will become wider and cannot be precisely defined. Hence, how to avoid the residue of photoresist left in the via hole and keep up the boundary of trench we defined are our subjects.

### SUMMARY

It is an object of the invention to provide a method for forming a dual damascene opening.

It is another object of the invention to provide a method to avoid the residue of photoresist left in via hole which will cause the etching profile of the trench distorted, such will affect the formation of dual damascene opening.

According to the foregoing objects, the present invention provides a method to form a dual damascene opening by a liquid phase deposition method which is a selectively depositing method. Firstly a photoresist is formed on a dielectric layer and patterned to define a via hole. Secondly, the dielectric layer is etched to form a via hole. Then, another photoresist is deposited on the dielectric layer to fill up the via hole, and then patterned to define photoresist mask. The space which the photoresist mask occupies is just used for the dual damascene opening. Then, silicon dioxide is deposited on the surface of the dielectric layer by liquid phase deposition method. Finally, the photoresist mask is removed to form a dual damascene opening. The liquid phase deposition is performed at a temperature range from about 25° C. to about 40° C., which is different from those prior deposition methods performed at a temperature about several hundred degrees centigrade. The liquid used in the liquid phase deposition method was prepared by dissolving highly purified silica particles in hydrofluosilicic acid at 35° C. to obtain a saturated solution with silica. The saturated solution is then filtered to remove undissolved silica. Then, boric acid was continuously added into the solution to obtain a supersaturated solution. Film deposition was carried out by only immersing substrate in the solution at the same temperature.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 shows a schematic cross-sectional diagram of a typical dual damascene opening;

FIG. 2A through FIG. 2E provide cross-sectional views at various stages in a prior via-first method used to form a dual damascene opening;

FIG. 3A through FIG. 3F provide cross-sectional views at various stages in a method containing the liquid phase deposition method to form a dual damascene opening.

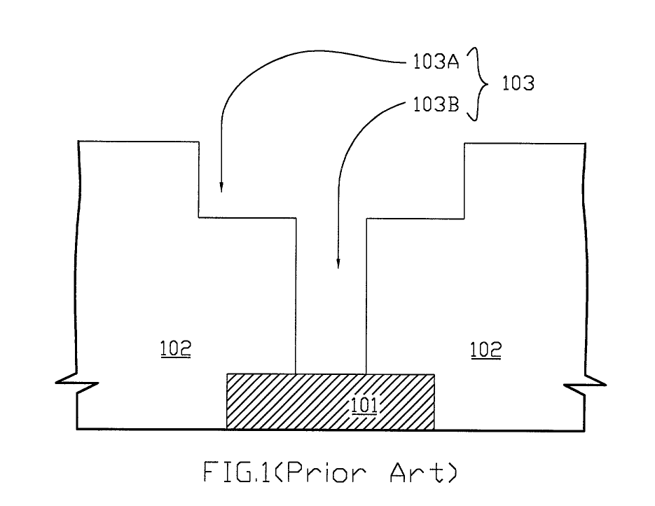

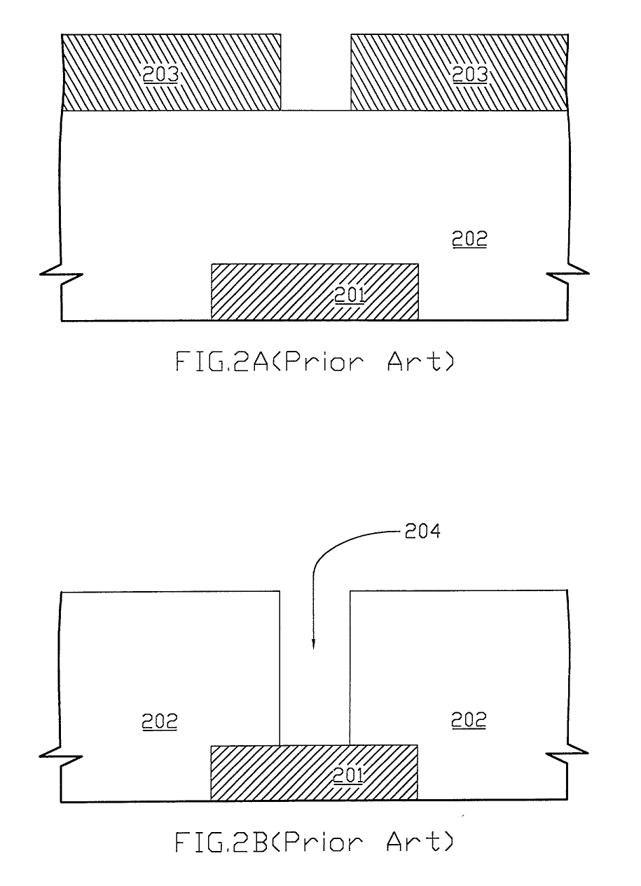

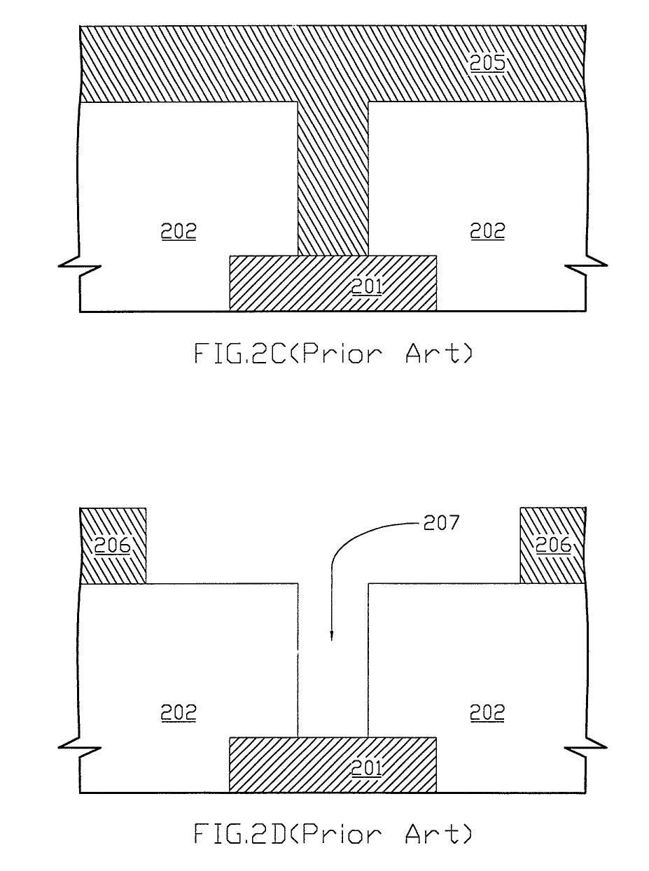

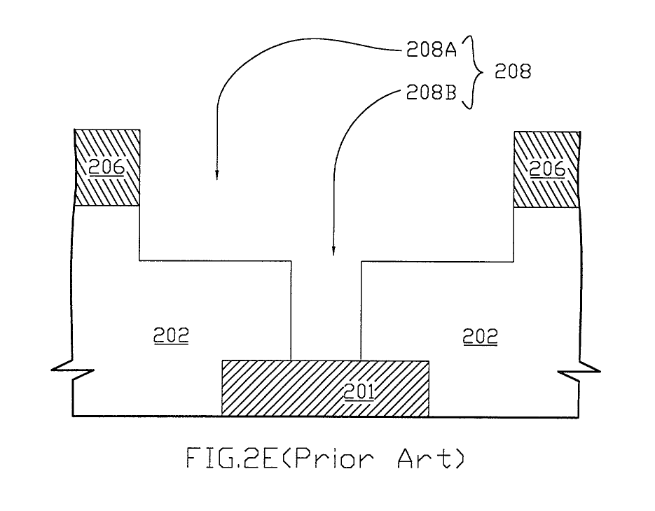

### DESCRIPTION OF THE PREFERRED EMBODIMENT

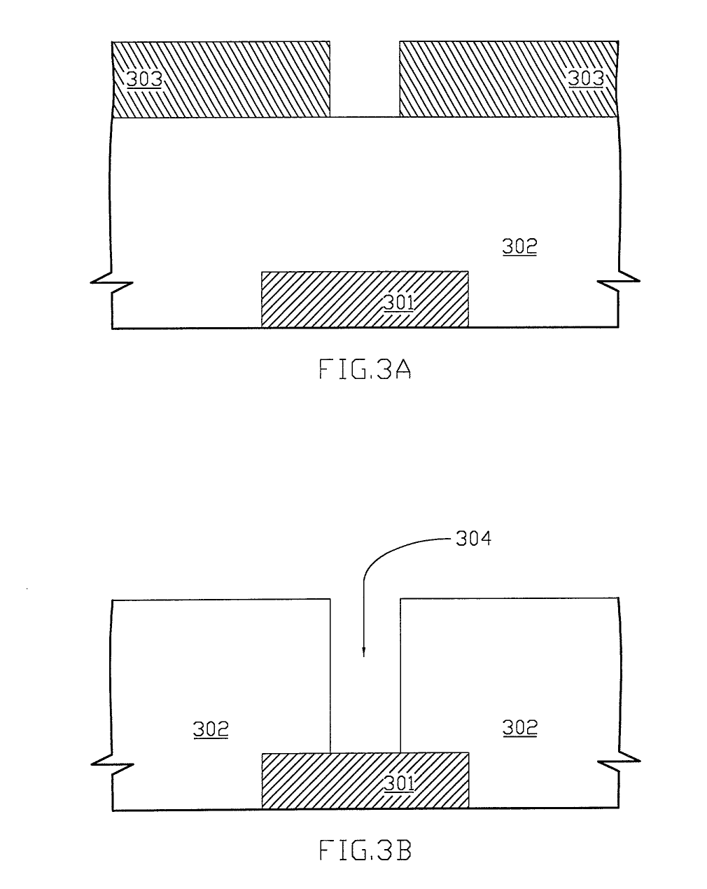

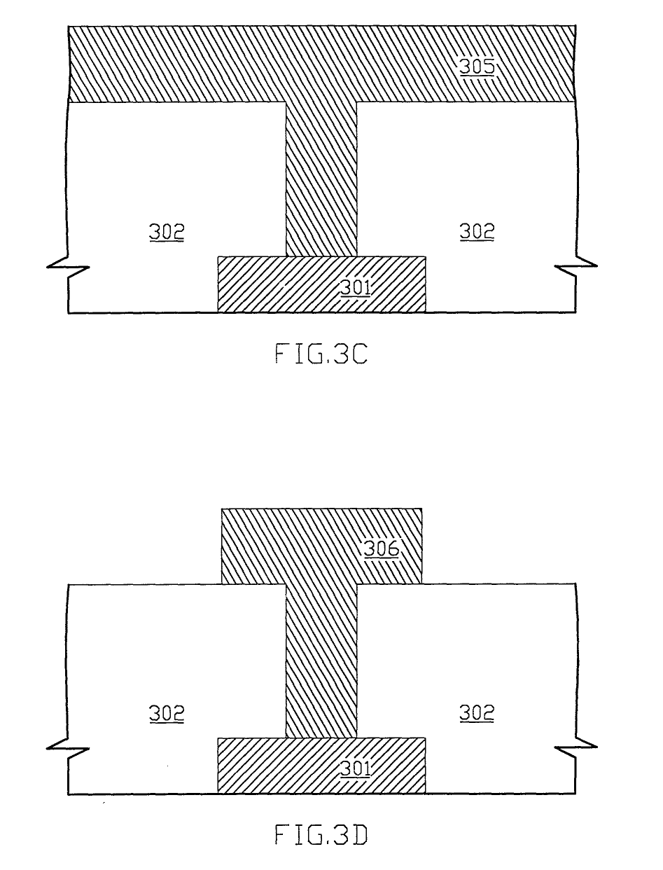

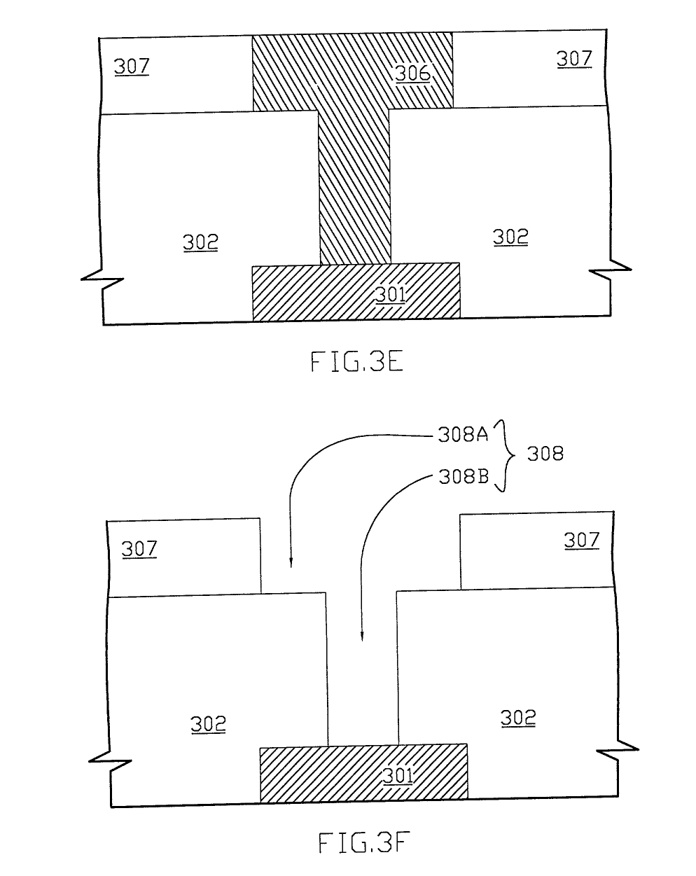

According to the foregoing objects, we provide a method in present invention to form a dual damascene opening by liquid phase deposition method which is a selectively depositing method. Firstly, as shown in FIG. 3A, a conductor 301 is provided and an inter-metal dielectric layer 302 is deposited to cover the conductor 301. The conductor 301 may be an interconnect or a semiconductor device such as an MOS. Then, a photoresist 303 is formed on the inter-metal dielectric layer 302 and is patterned to define a via hole. Secondly, the inter-metal dielectric layer 302 is etched onto the surface of the conductor 301, so that a via hole 304 is formed and a partial region of the conductor 301 is also exposed. Then, the photoresist 303 is removed, as shown in FIG. 3B. Another photoresist 305 is then deposited on the surface of the inter-metal dielectric layer 302 and to fill up the via hole 304, as shown in FIG. 3C. Then, the photoresist 305 is patterned to define a photoresist mask 306. The photoresist mask 306 is positioned on the via hole 304, and the space the photoresist mask occupies is just used for the dual damascene opening. The part of photoresist 305 which is not used to be the photoresist mask 306 is removed, as shown in FIG. 3D. The liquid phase deposition is then performed, and silicon dioxide 307 is selectively deposited on the surface of the inter-metal dielectric layer 302, but no silicon dioxide is deposited on the photoresist mask 306, as shown in FIG. 3E. Finally, the photoresist mask 306 which is on the inter-metal dielectric layer 302 and in the via hole 304 is removed by oxygen plasma etching or solvent. Hence, a dual damascene opening 308 consisting of a trench 308A and a via hole 308B is then formed, as shown in FIG. 3F.

The mentioned silicon dioxide is formed by using liquid phase deposition method at a temperature range from 25° C. to 40° C., which is different from the prior deposition methods. Most of the prior deposition methods are performed at a temperature about several hundred degrees centigrade, for example, a typical TEOS silicon dioxide is deposited at a temperature from about 650° C. to about 750° C. The liquid phase deposition can avoid some problems caused by high temperature such as metal diffusion. The liquid used in the liquid phase deposition method was prepared by dissolving highly purified silica particles into hydrofluosilicic acid at 35° C. to obtain a saturated solution with silica. The saturated solution is then filtered to remove undissolved silica. Then, boric acid was continuously added into the solution to obtain a supersaturated solution. Film deposition was carried out by only immersing substrate into the solution at the same temperature.

Although specific embodiments have been illustrated and described, it will be obvious to those skilled in the art that various modifications may be made without departing from what is intended to be limited solely by the appended claims.

What is claimed is:

1. A method for forming a dual damascene opening, said method comprising the steps of:
providing a structure, said structure comprises a conductive layer, a first dielectric layer deposited on the surface of said conductive layer, and a via hole formed in said first dielectric layer to expose a partial region of said conductive layer;
depositing a photoresist on the surface of said first dielectric layer and in said via hole so that said via hole is filled up;
patterning said photoresist to define a photoresist mask and expose a plurality of partial region of said first dielectric layer, wherein a part of said photoresist mask is formed over said via hole and the other part of said photoresist mask is in said via hole;
depositing a plurality of second dielectric layers on the surface of said plurality of partial region of said first dielectric layer; and
removing said photoresist mask to form a dual damascene opening.

2. The method according to claim 1, wherein said conductive layer is a semiconductor device.

3. The method according to claim 1, wherein said conductive layer is an interconnect.

4. The method according to claim 1, wherein the step of depositing a plurality of second dielectric layers is performed by liquid phase deposition.

5. The method according to claim 4, wherein said liquid phase deposition is a selectively depositing method.

6. The method according to claim 4, wherein said liquid phase deposition is performed at a temperature range from about 20° C. to about 40° C.

7. The method according to claim 1, wherein the step of removing said photoresist mask is performed by an oxygen plasma etching.

8. A method for forming a dual damascene opening, said method comprising the steps of:
providing a structure, said structure comprises a conductive layer, a first dielectric layer deposited on the surface of said conductive layer, and a via hole formed in said first dielectric layer to expose a partial region of said conductive layer;
depositing a photoresist on the surface of said first dielectric layer and in said via hole so that said via hole is filled up;
patterning said photoresist to define a photoresist mask and expose a plurality of partial region of said first dielectric layer, wherein a part of said photoresist mask is formed over said via hole and the other part of said photoresist mask is in said via hole;
depositing a plurality of second dielectric layers on the surface of said plurality of partial region of said first dielectric layer by liquid phase deposition; and
removing said photoresist mask to form a dual damascene opening.

9. The method according to claim 8, wherein said conductive layer is a semiconductor device.

10. The method according to claim 8, wherein said conductive layer is an interconnect.

11. The method according to claim 8, wherein said liquid phase deposition is a selectively depositing method.

12. The method according to claim 8, wherein said liquid phase deposition is performed at a temperature range from about 20° C. to about 40° C.

13. The method according to claim 8, wherein the step of removing said photoresist mask is performed by an oxygen plasma etching.
